(19) United States
(12) Patent Application Publication
(10) Pub. No.: US 2012/0040136 A1
(43) Pub. Date: Feb. 16, 2012

(54) CERAMIC COATING, ARTICLE COATED WITH COATING, AND METHOD FOR MANUFACTURING ARTICLE

(75) Inventors: QI-JIAN DU, Shenzhen City (CN); CHWAN-HWA CHIANG, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/158,568

(22) Filed: Jun. 13, 2011

(30) Foreign Application Priority Data
Aug. 12, 2010 (CN) 201010251955.6

(51) Int. Cl. B32B 18/00; B32B 3/00; C23C 14/08

(52) U.S. Cl. 428/142; 428/151; 204/192.11

(57) ABSTRACT

A ceramic coating comprised of alumina or zirconia. The ceramic coating defines a plurality of recesses on surface, giving a leather-like appearance thereon. The ceramic coating is formed by ion beam assisted evaporation.

### BACKGROUND

1. Technical Field

The exemplary disclosure generally relates to ceramic coatings, and particularly relates to articles coated with the ceramic coatings and method for manufacturing the articles.

2. Description of Related Art

Electroplating is used to form coatings on the housings of electronic devices. However, electroplating cannot directly coat patterns on a substrate without any other additional processing. Furthermore, electroplating can be environmentally unfriendly.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary ceramic coating, article coated with coating, and method for manufacturing article. Moreover, in the drawings like reference numerals designate corresponding parts throughout the several views. Wherever possible, the same reference numbers are used throughout the drawings to refer to the same or like elements of an embodiment.

FIG. 1 is a top view of an exemplary article coated with a ceramic coating.

FIG. 2 is a cross-sectional view of an exemplary article in FIG. 1.

FIG. 3 is a schematic view of an evaporation machine for manufacturing the article in FIG. 1.

### DETAILED DESCRIPTION

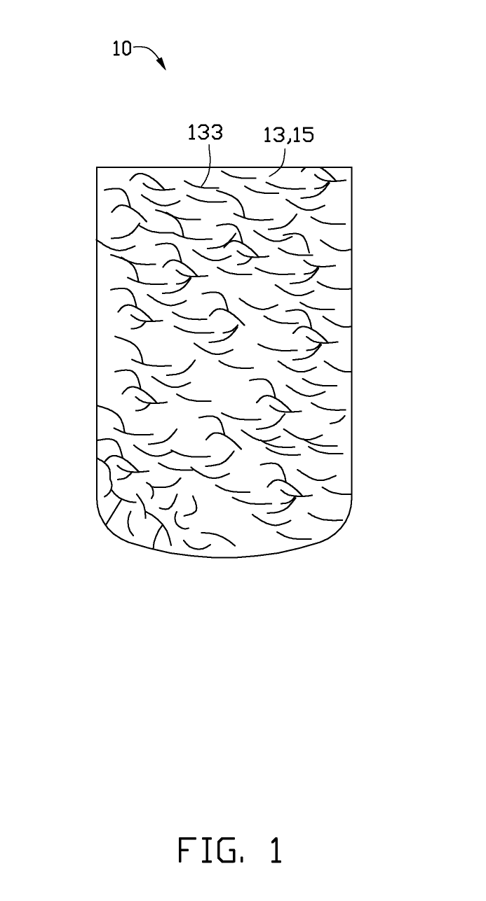

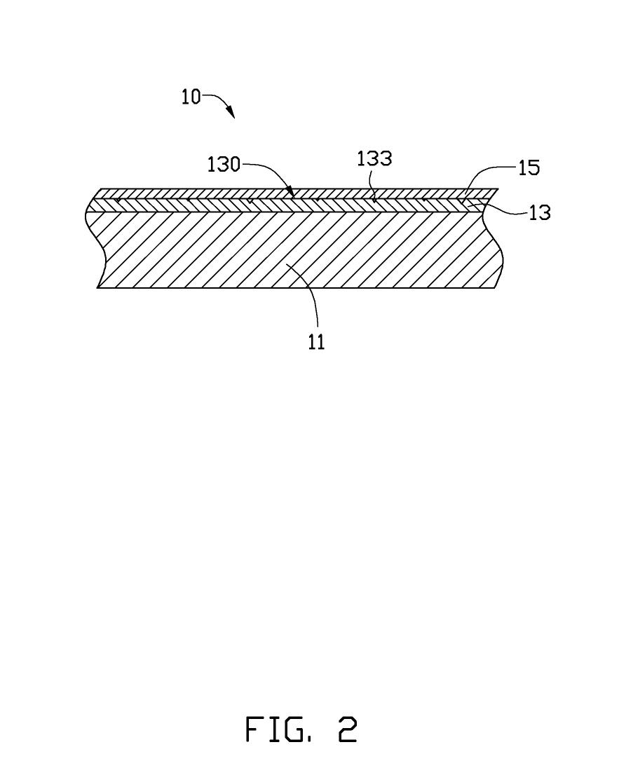

Referring to FIGS. 1 and 2, an exemplary ceramic coating 13 is composed of alumina or zirconia. The ceramic coating 13 defines a plurality of recesses 133 on a surface 130. These recesses 133 give the coating 13 a leather-like appearance. The recesses 133 may intersect with each other. The ceramic coating 13 is formed by a physical vapor deposition (PVD) process, such as ion beam assisted evaporation. Also, the ceramic coating 13 is nonconductive so as to not block electromagnetic waves. The thickness of the ceramic coating 13 is about 10 nm-200 nm.

Referring to FIG. 2, an exemplary article 10 includes a substrate 11 and the ceramic coating 13 is deposited on the substrate 11. The substrate 11 may be made of plastic materials, such as polycarbonate (PC), polyethylene (PE), polymethyl methacrylate (PMMA), or acrylonitrile-butadiene-styrene (ABS). The substrate 11 also may be made of metal, ceramic, or glass. In this exemplary embodiment, the ceramic coating 13 is composed of alumina. The article 10 may be a housing of an electronic device. It is to be understood that the article 10 may further include a transparent protective layer 15 formed on the ceramic coating 13 for protecting the ceramic coating 13. The protective layer 15 may comprise a single layer or multiple layers of transparent paint. The paint may be thermal-curable or photo-curable paint. The thickness of the protective layer 15 is about 10 μm-50 μm. The protective layer 15 may contain colorant therein, presenting desired color for the article 10.

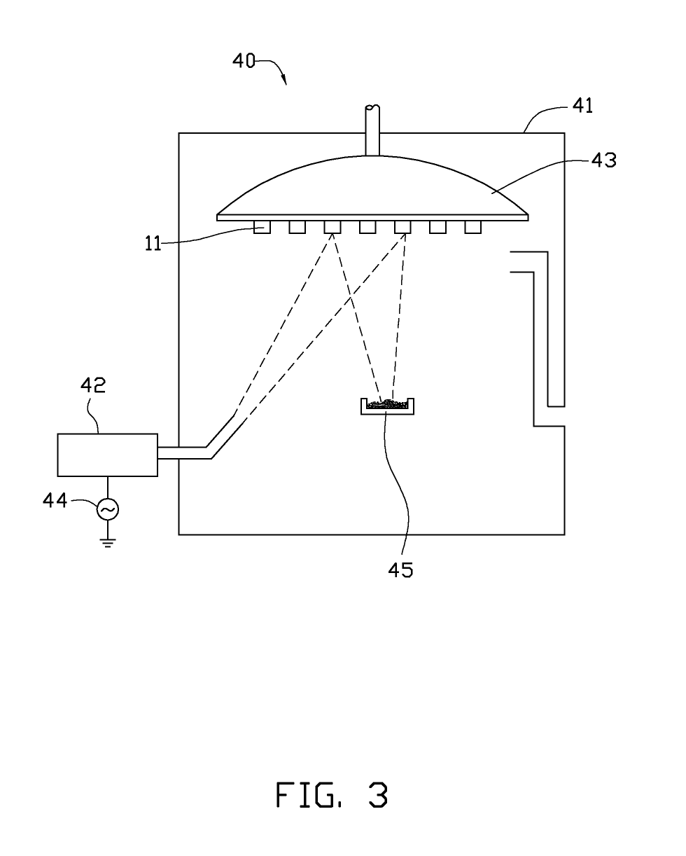

Referring to FIGS. 2 and 3, an exemplary method for manufacturing the article 10 may include at least the following steps.

The substrate 11 is provided.

The substrate 11 may be pretreated by ultrasonic cleaning, to remove impurities such as grease or dirt from the substrate 11.

The ceramic coating 13 is formed on the substrate 11 by ion beam assisted evaporation. An exemplary ion beam assisted evaporation process for forming the ceramic coating 13 may be performed by the following steps.

Before depositing the ceramic coating 13, the substrate 11 is cleaned by plasma cleaning. The substrate 11 is held by a rotating bracket 43 in a vacuum chamber 41 of an evaporation machine 40 as shown in FIG. 3. The machine 40 includes a plasma source 42 coupled with a power source 44. Plasma is generated by utilizing the power source 44 to dissociate ions from a processing gas, such as argon, thereby forming a supply of ions that can accelerate toward the substrate 11. The vacuum chamber 41 maintains an internal pressure of about 5.0×10⁻³ Pa-5.0×10⁻² Pa. The temperature in the vacuum chamber 41 is maintained at about 50° C.-70° C. The potential of the power source 44 may be controlled in a range of about 110 volts (V)-130V with a current density in a range of about 2.5 A-3.5 A to form an ion beam. The ion beam bombards the substrate 11 for about 50 second (sec)-90 sec, further removing any impurities thereon. Thus, bonding between the substrate 11 and the ceramic coating 13 will be enhanced. In this exemplary embodiment, the potential of the power source 44 is about 120V with a current density of about 3 A. The duration of plasma cleaning is about 60 sec.

Once the plasma cleaning is finished, oxygen is supplied into the vacuum chamber 41 to compensate for the oxygen atoms lost during the deposition. The oxygen creates a working atmospheric pressure of about 1.5×10⁻³ Pa-9.5×10⁻³ Pa in the vacuum chamber 41. The temperature in the vacuum chamber 41 is maintained at about 50° C.-70° C. Evaporation source 45 of crystal alumina or zirconia is evaporated at a rate of about 2.0 angstroms per second (Å/s)-4.5 Å/s to deposit the ceramic coating 13 by electron beam evaporation. The ion beam bombards the substrate 11 during the ceramic coating 13 deposition. The ion beam is generated by controlling the potential of the power source 44 in a range of 140V-160V with a current density in a range of 4.5 A-5.5 A. The ceramic coating 13 having the recesses 133, which presents a leather-like appearance, is formed in this step. In this exemplary embodiment, the potential of the power source 44 is about 150V with a current density of about 4 A, and the target is crystal alumina.

During the deposition of the ceramic coating 13, the ion beam bombards the ceramic coating 13, thereby portions of the ceramic coating 13 may be removed to form the recesses 133. The presence of the ion beam during the deposition of the ceramic coating 13 also enhances the packing density of the ceramic coating 13.

After the deposition of the ceramic coating 13 is finished, the substrate 11 with the ceramic coating 13 is retained in the vacuum chamber 41 and continuously bombarded by the ion beam for about 3 min-10 min. In this step, the potential of the power source 44 is controlled in a range of 140V-160V with a current density in a range of about 3.5 A-4.5 A. In this exemplary embodiment, the potential of the power source 44 is about 150 volts with a current density of about 4 A. The presence of the ion beam after the deposition of the ceramic coating 13 enhances the bonding of the ceramic coating 13 and the substrate 11 and etches the recesses 133.

Owing to the present process, an article 10 having a leather-like appearance is obtained.

Additionally, the method for manufacturing the article may further include forming the transparent protective layer 15 on the ceramic coating 13, which can be achieved by spray painting.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A ceramic coating, the ceramic coating being composed of alumina or zirconia and defining a plurality of recesses on its surface, giving the ceramic coating a leather-like appearance.

2. The ceramic coating as claimed in claim 1, wherein the recesses intersect with each other.

3. The ceramic coating as claimed in claim 1, wherein the ceramic coating is formed by ion beam assisted evaporation.

4. The ceramic coating as claimed in claim 1, wherein the ceramic coating has a thickness of about 10 nm-200 nm.

5. The process as claimed in claim 4, wherein the ceramic coating is non-conductive.

6. An article, comprising:
a substrate; and
a ceramic coating formed on the substrate, the ceramic coating being composed of alumina or zirconia and defining a plurality of recesses on its surface, giving the ceramic coating a leather-like appearance.

7. The article as claimed in claim 6, wherein the substrate is made of one of the materials elected from the group consisting of plastic, metal, ceramic, and glass.

8. The article as claimed in claim 6, wherein the recesses intersect with each other.

9. The article as claimed in claim 6, wherein the ceramic coating is formed by ion beam assisted evaporation.

10. The article as claimed in claim 6, wherein the ceramic coating has a thickness of about 10 nm-200 nm.

11. The article as claimed in claim 6, further comprising a transparent protective layer formed on the ceramic coating.

12. The article as claimed in claim 11, wherein protective layer comprises a single layer or multiple layers of transparent paint.

13. A method for manufacturing an article, comprising steps of:
providing a substrate;
forming a ceramic coating on the substrate, the ceramic coating being composed of alumina or zirconia and defining a plurality of recesses on its surface, giving the ceramic coating a leather-like appearance.

14. The method as claimed in claim 13, wherein ceramic coating is deposited by ion beam assisted evaporation.

15. The method as claimed in claim 14, wherein during the ion beam assisted evaporation of the ceramic coating, the substrate is placed in a vacuum chamber of a evaporation machine; oxygen is supplied into the vacuum chamber; the temperature in the vacuum chamber is maintained at about 50° C.-70° C.; an evaporation source of crystal alumina or zirconia is evaporated at a rate of about 2.0 Å/s-4.5 Å/s; ion beam generated by applying a power source at a potential in a range of about 140V-160V with a current density in a range of about 4.5 A-5.5 A bombards the substrate.

16. The method as claimed in claim 15, wherein the oxygen creates a working atmospheric pressure of about 1.5×10⁻³ Pa-9.5×10⁻³ Pa in the vacuum chamber.

17. The method as claimed in claim 14, further comprising a step of continuously bombarding the substrate with the ceramic coating by ion beam for about 3 min-10 min after the deposition of the ceramic coating.

18. The method as claimed in claim 17, wherein the ion beam is generated by applying a power source at a potential of about 140V-160V with a current density of about 4.5 A-5.5 A.

19. The method as claimed in claim 14, further comprising a step of plasma cleaning the substrate before the ion beam assisted evaporation of the ceramic coating.

20. The method as claimed in claim 13, further comprising a step of forming a protective layer of transparent paint on the ceramic coating.
